(19) United States
(12) Patent Application Publication
(10) Pub. No.: US 2020/0365767 A1
(43) Pub. Date: Nov. 19, 2020

(54) LIGHT-EMITTING DIODE STRUCTURE AND METHOD FOR FORMING THE SAME

(71) Applicant: SHIN-ETSU OPTO ELECTRONIC CO., LTD., Hsinchu (TW)

(72) Inventors: MUNEHISA YANAGISAWA, HSINCHU COUNTY (TW); CHUN-NENG HUANG, MIAOLI COUNTY (TW); CHI-HUNG FENG, MIAOLI COUNTY (TW); HSING-HSUAN LO, MIAOLI COUNTY (TW); TING-WEI CHANG, NEW TAIPEI CITY (TW); YI-HSIANG CHIU, MIAOLI COUNTY (TW)

(21) Appl. No.: 16/667,769

(22) Filed: Oct. 29, 2019

Related U.S. Application Data
(60) Provisional application No. 62/849,623, filed on May 17, 2019.

(51) Int. Cl. H01L 33/38; H01L 33/30; H01L 33/42; H01L 33/14

(52) U.S. Cl. CPC H01L 33/38; H01L 33/305; H01L 33/06; H01L 33/14; H01L 33/42

(57) ABSTRACT

A light-emitting diode structure includes a substrate, a light-generating structure disposed over the substrate, a first electrode adjacent to a first side of the light-generating structure, a second electrode adjacent to a second side of the light-generating structure opposite to the first side, and a tungsten-doped oxide layer disposed in an electrical conduction path between the light-generating structure and one of the first electrode and the second electrode.

### PRIOR CLAIM AND CROSS-REFERENCE

This application claims priority to U.S. Provisional Application No. 62/849,623 filed on May 17, 2019, the disclosure of which is hereby incorporated by reference in its entirety.

### BACKGROUND

Light-emitting diodes (LEDs) have gained increased popularity in the fields of lighting and display and have become indispensable for industrial and commercial products in home, car, office and outdoor environments. Typically, the LED includes a light-generating stack for transforming injected electrons into light. Additional layers may be disposed between the electrodes and the light-generating stack for improving the optical performance and efficiency of the light-generating stack.

BRIEF SUMMARY OF THE INVENTION

In conventional visible-light LEDs, a conductive layer, e.g., a tin-based oxide layer, is generally adopted to improve the electrical conductivity and transmittance of light at wavelengths of visible light. However, the conductive layer may not provide desirable transmittance at wavelengths outside those of visible light. Therefore, there is a need to improve the optical performance of the conventional LED by using a conductive transparent layer having high transmittance at wavelengths across the spectrum of visible and non-visible wavelengths.

The present disclosure is directed to a light-emitting diode (LED) structure in which a spreading layer is disposed therein for improving current spreading and electromagnetic radiation emission. In some embodiments, the spreading layer is disposed between an electrode and a light-generating structure. In some embodiments, the spreading layer is a tungsten-doped oxide layer. In some embodiments, the spreading layer is a tungsten-doped indium oxide or an indium tungsten oxide (IWO) layer. In some embodiments, the spreading layer is used as a transparent conductive film for the LED structure. In some embodiments, the spreading layer may form an electrical (e.g., ohmic) junction with a P-type semiconductor layer of the light-generating structure.

According to one aspect of the present invention, a light-emitting diode structure including a substrate, a light-generating structure disposed over the substrate, a first electrode disposed adjacent to a first side of the light-generating structure, a second electrode disposed adjacent to a second side of the light-generating structure opposite to the first side, and a tungsten-doped oxide layer disposed in an electrical conduction path between the light-generating structure and one of the first electrode and the second electrode.

According to one aspect of the present invention, a light-emitting diode includes a substrate having a first side, a light-generating structure disposed over the first side of the substrate, a first electrode disposed over the tungsten-doped oxide layer and the first side of the substrate, a second electrode disposed over the first side of the substrate, and a tungsten-doped oxide layer disposed in an electrical conduction path between the light-generating structure and one of the first electrode and the second electrode.

According to one aspect of the present invention, a light-emitting diode includes a substrate, a bonding layer over the substrate, a tungsten-doped oxide layer having a first side and disposed over the bonding layer, a light-generating structure disposed over the first side of the tungsten-doped oxide layer, a first electrode disposed over the light-generating structure, and a second electrode disposed adjacent to the light-generating structure and over the first side of the tungsten-doped oxide layer.

Various objects, features, aspects, and advantages of the present invention will become more apparent from the following detailed description of preferred embodiments of the invention, along with the accompanying drawings in which like numerals represent like components.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of an LED device, in accordance with some embodiments of the present invention,

FIGS. 2A and 2B are cross-sectional views of LED devices, in accordance with some embodiments of the present invention.

FIGS. 3A and 3B are cross-sectional views of LED devices, in accordance with some embodiments of the present invention.

FIGS. 4A to 4C are cross-sectional views of LED devices, in accordance with some embodiments of the present invention.

FIG. 5 is cross-sectional views of LED devices, in accordance with some embodiments of the present invention.

FIGS. 6A and 6B are graphs showing simulation results of the transmittance levels of LED devices, in accordance with some embodiments of the present invention.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 70 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” and “substantially” generally mean within 10%, 5%, 1% or 0.5% of a given value or range. Alternatively, the terms “about,” “substantial” and “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The present invention is directed to an LED structure for increasing emission efficiency. The LED structure may be implemented as a vertical type, a planar type, a. vertical metal bonding type, a planar metal bonding type or a planar transparent bonding type.

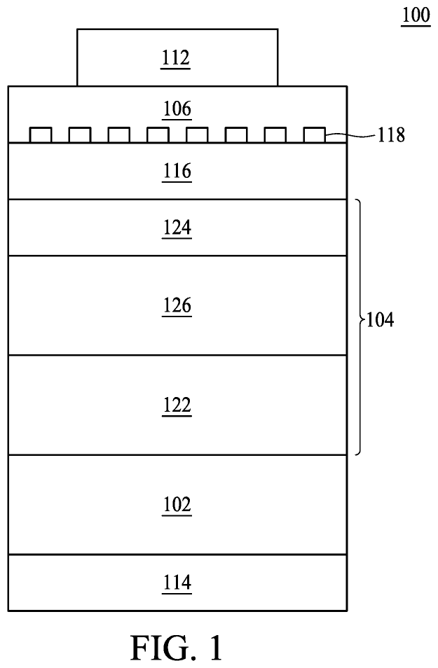

FIG. 1 is a first embodiment 100 of an LED structure in accordance with some embodiments of the present invention. In some embodiments, the first embodiment 100 is a vertical type LED structure. In some embodiments, the first embodiment 100 emits electromagnetic radiation at wavelengths between about 1200 nm and about 1550 nm. Referring to FIG. 1, the first embodiment 100 includes a substrate 102, a light-generating structure 104 over the substrate 102, and a spreading layer 106 over the light-generating structure 104. The substrate 102 has a lower side and an upper side opposite to the lower side, in which the upper side faces the light-generating structure 104.

In some embodiments, the substrate 102 is a conductive substrate, such as a substrate made of a metallic material. In some embodiments, the substrate 102 is transparent or opaque. In some embodiments, the substrate 102 is a semiconductive substrate. In some embodiments, the substrate 102. includes semiconductive material such as Si, Ge, GaP, GaAs, InP, InAs, InSb, GaN, or the like.

The light-generating structure 104 is configured to emit photons in response to a current injected into the light-generating structure 104, The light-generating structure 104 may comprise an N-type semiconductor layer (N-layer) 122, a P-type semiconductor layer (P-layer) 124, and a light-emitting layer 126 between the N-type semiconductor layer 122 and the P-type semiconductor layer 124. The light-emitting layer 126, also referred to as an active layer, may be formed of multiple quantum well (MQW) structures, and is thus sometimes referred to as an MQW layer. The N-type and P-type semiconductor layers 122 and 124 may be referred to as the cladding layers.

The light-generating structure 104 may have a first side adjacent to the N-type semiconductor layer 122 and a second side opposite to the first side and adjacent to the P-type semiconductor layer 124. In the depicted embodiment, the upper side of the substrate 102 faces the first side of the light-generating structure 104, Throughout the present disclosure, the side of the light-generating structure 104 adjacent to the N-type semiconductor layer 122 is referred to as an N-side, and the side of the light-generating structure 104 adjacent to the P-type semiconductor layer 124 is referred to as a P-side.

In some embodiments, the semiconductor layers 122, 124 and 126 of the light-generating structure 104 include semiconductive materials such as AlP, GaP, InP, AlGaP, AlInP, GaInP, AlGaInP, AlAs, GaAs, InAs, AlGaAs, AlInAs, GaInAs, AlGaInAs, AlAsP, GaAsP, InAsP, AlGaAsP, AlInAsP, GaInAsP, AlGaInAsP or the like. In some embodiments, the semiconductor layers 122, 124 and 126 of the light-generating structure 104 include semiconductive materials such as AlSb, GaSb, InSb, AlGaSb, AllnSb, GalnSb, AlGaInSb, AlPSb, GaPSb, InPSb, AlGaPSb, AlInPSb, GaInPSb, AlGaInPSb, AlAsSb, GaAsSb, InAsSb, AlGaAsSb, AlInAsSb, GaInAsSb, AlGalnAsSb, AlPAsSb, GaPAsSb, InPAsSb, AlGaPAsSb, AlInPAsSb, GaInPAsSb, AlGaInPAsSb or the like.

In some embodiments, the N-type semiconductor layer 122 is doped with N-type dopants, e.g., silicon. In some embodiments, the P-type semiconductor layer 124 is doped with P-type dopants, e.g., magnesium, zinc or carbon.

A first electrode 112, which may be referred to as a P-side electrode, is disposed adjacent to the P-type semiconductor layer 124 of the light-generating structure 104 and over the spreading layer 106, and a second electrode 114, which may be referred to as an N-side electrode, is disposed adjacent to the N-type semiconductor layer 122 of the light-generating structure 104 and beneath the substrate 102.

In some embodiments, the spreading layer 106 is a tungsten-doped oxide (or indium tungsten oxide, IWO) layer. In some embodiments, the spreading layer 106 is a zinc tungsten oxide (ZnWO) layer, a copper tungsten oxide (or copper tungstate, CuWO) layer or other transparent conductive layer. In some embodiments, the spreading layer 106 has a thickness between about 500 Angstrom (Å) and about 5000 Å, or between about 1500 Angstrom (Å) and about 2500 Å. In some embodiments, the spreading layer 106 has a thickness between about 1550 Å and about 1650 Å, such as about 1600 Å.

In some embodiments, a transmittance of the spreading layer 106 using a tungsten-doped oxide material for electromagnetic radiation at wavelengths between about 500 nm and about 2500 nm is substantially greater than or equal to about 30%, or greater than or equal to about 50%. In some embodiments, a transmittance of the spreading layer 106 using a tungsten-doped oxide material for electromagnetic radiation at wavelengths between about 500 nm and about 2500 nm is substantially greater than or equal to 70%.

In some embodiments, a transmittance of the spreading layer 106 using a tungsten-doped oxide material for an electromagnetic radiation at wavelengths between about 500 nm and about 1500 nm is substantially greater than or equal to about 80%, or greater than or equal to 90%. In some embodiments, a transmittance of the spreading layer 106 using a tungsten-doped oxide material for electromagnetic radiation at wavelengths between about 500 nm and about 1500 nm is substantially greater than or equal to 95%.

In some embodiments, a transmittance of the spreading layer 106 using a tungsten-doped oxide material for electromagnetic radiation at wavelengths between about 900 nm and about 2500 nm is substantially greater than or equal to about 30%, or greater than or equal to 50%. In some embodiments, a transmittance of the spreading layer 106 using a tungsten-doped oxide material for an electromagnetic radiation at wavelengths of about 900 nm to about 2500 nm is substantially greater than or equal to 70%.

In some embodiments, a transmittance ratio of the spreading layer 106 using a tungsten-doped oxide material for an electromagnetic radiation in a first wavelength of about 2500 nm to an electromagnetic radiation at a second wavelength of about 500 nm is substantially greater than or equal to 50%. In some embodiments, a transmittance ratio of the spreading layer 106 using a tungsten-doped oxide material for an electromagnetic radiation in a first wavelength of about 1500 nm to the electromagnetic radiation at a second wavelength of about 500 nm is substantially greater than or equal to 70%, or greater than or equal to 80%.

In some embodiments, a transmittance ratio of the spreading layer 106 using a tungsten-doped oxide material for an electromagnetic radiation in a first wavelength of about 2500 nm to the electromagnetic radiation at a second wavelength of about 900 nm is substantially greater than or equal to 50%. In some embodiments, a transmittance ratio of the spreading layer 106 using a tungsten-doped oxide material for an electromagnetic radiation in a first wavelength of about 2500 nm to the electromagnetic radiation at a second wavelength of about 900 nm is substantially greater than or equal to 70%.

In some embodiments, a transmittance of the spreading layer 106 using a tungsten-doped oxide material for an electromagnetic radiation at a wavelength of about 1500 um is substantially greater than or equal to 90%. In some embodiments, a transmittance of the spreading layer 106 using a tungsten-doped oxide material for an electromagnetic radiation at a wavelength of about 2500 nm is substantially greater than or equal to 50%.

In some embodiments, the first electrode 112 includes metallic material such as gold (Au), chromium (Cr) or the like. In some embodiments, the second electrode 114 includes metallic material such as gold (Au), AuGe, nickel (Ni) or the like.

In some embodiments, the first embodiment 100 further includes a first contact layer 116 (which may be referred to as a P-side contact layer or a P-contact layer) coupling the P-type semiconductor layer 124 to the spreading layer 106. In some embodiments, the spreading layer 106 is in contact with the P-type semiconductor layer 124 if the first contact layer 116 is absent. In some embodiments, the first contact layer 116 is disposed between the first electrode 112 and the light-generating structure 104

In some embodiments, the first contact layer 116 may be formed of a semiconductive material. In some embodiments, the first contact layer 116 includes semiconductive material such as AlP, GaP, InP, AlGaP, AlInP, GaInP, AlGaInP, AlAs, GaAs, InAs, AlGaAs, AlInAs, GaInAs, AlGaInAs, AlAsP, GaAsP, InAsP, AlGaAsP, AlInAsP, GaInAsP, AlGaInAsP, or the like. In other embodiments, the first contact layer 116 includes semiconductive material such as AlSb, GaSb, InSb, AlGaSb, AlInSb, GaInSb, AlGaInSb, AlPSb, GaPSb, InPSb, AlGaPSb, AlInPSb, GaInPSb, AlGaInPSb, AlAsSb, GaAsSb, InAsSb, AlGaAsSb, AlInAsSb, GalnAsSb, AlGaInAsSb, AlPAsSb, GaPAsSb, InPAsSb, AlGaPAsSb, AlInPAsSb, GaInPAsSb, AlGaInPAsSb, or the like.

In some embodiments, the first contact layer 116 is doped with a dopant, such as zinc, magnesium, carbon or other suitable acceptors, for increasing electrical conductivity of the first contact layer 116. In some embodiments, the first contact layer 116 is doped with a dopant concentration substantially greater than or equal to 1E18 atoms/cm³. In some embodiments, the first contact layer 116 is doped with a dopant concentration substantially greater than or equal to 2E18 atoms/cm³.

In some embodiments, an intermediate member 118 is disposed between the spreading layer 106 and the first contact layer 116 (or between the spreading layer 106 and the P-type semiconductor layer 124 if the first contact layer 116 is absent) for forming or improving the electrical (e.g., ohmic) contact between the P-type semiconductor layer 124 and the spreading layer 106. In some embodiments, the intermediate member 118 is transparent or opaque. In some embodiments, the intermediate member 118 is conductive. In some embodiments, the intermediate member 118 contains metal or metallic material. In some embodiments, the intermediate member 118 includes indium tin oxide (ITO). In some embodiments, the intermediate member 118 includes gold (Au), nickel (Ni), chromium (Cr), aluminum (Al), titanium (Ti), silver (Ag), platinum (Pt) or any other suitable material.

In some embodiments, portions of the underlying first contact layer 116 or the P-type semiconductor layer 124 (if the first contact layer 116 is absent) are exposed from the intermediate member 118. In some embodiments, the intermediate member 118 can be in different shapes, such as a ring or an array of conductive dots from a top-view perspective, over the first contact layer 116 and to expose the first contact layer 116. The intermediate member 118 is configured to electrically couple the spreading layer 106 to the P-type semiconductor layer 124.

In some embodiments, the spreading layer 106 is disposed in an electrical conduction path that extends from the first electrode 112 to the second electrode 114, and also runs through the first contact layer 116, the light-generating structure 104, and the substrate 102. The spreading layer 106 may have good transmittance at wavelengths of light both within and outside of the visible range, and may improve the current-spreading efficiency of the LED.

The following description discusses a manufacturing process of the first embodiment 100 of the LED structure. The light-generating structure 104 is deposited, e.g., using epitaxial growth, over the substrate 102. In some embodiments, the N-type semiconductor layer 122, the light-emitting layer 126 and the P-type semiconductor layer 124 are sequentially grown over the substrate 102. In some embodiments, the spreading layer 106 is formed over the P-type semiconductor layer 124 by vacuum evaporation, vacuum coating or any other suitable operation. In some embodiments, the spreading layer 106 is coated over the P-type semiconductor layer 124 at a temperature of about 325° C., in some embodiments, the spreading layer 106 is coated over the P-type semiconductor layer 124 at a pressure of about 3E-6 torr. In some embodiments, during the coating of the spreading layer 106, an oxygen flow rate is about 4.6 sccm. Once disposing the spreading layer 106 over the P-type semiconductor layer 124, an ohmic contact between the P-type semiconductor layer 124 and the spreading layer 106 is formed. In some embodiments, the intermediate member 118 is formed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent).

In some embodiments, the first electrode 112 is also formed by vacuum evaporation, vacuum coating or any other suitable operation. In some embodiments, the first electrode 112 is formed using a vacuum deposition process. After disposing material of the first electrode 112 over the spreading layer 106, the material of the first electrode 112 is patterned into the first electrode 112 as desired by photolithography, etching or any other suitable operation. Subsequently, an annealing process is performed for improving an adhesion between the first electrode 112 and the spreading layer 106. The annealing is performed at a temperature between 330° C. and 380° C.

In some embodiments, the substrate 102 is thinned to a desired thickness by grinding, etching or any other suitable technique. In some embodiments, the second electrode 114 is formed by vacuum evaporation, vacuum coating or any other suitable operation. In some embodiments, a vacuum deposition process is performed for forming the second electrode 114. After disposing the second electrode 114 over the substrate 102, an annealing process is performed at a temperature between 330° C. and 380° C., such that an ohmic contact between the second electrode 114 and the substrate 102 is formed.

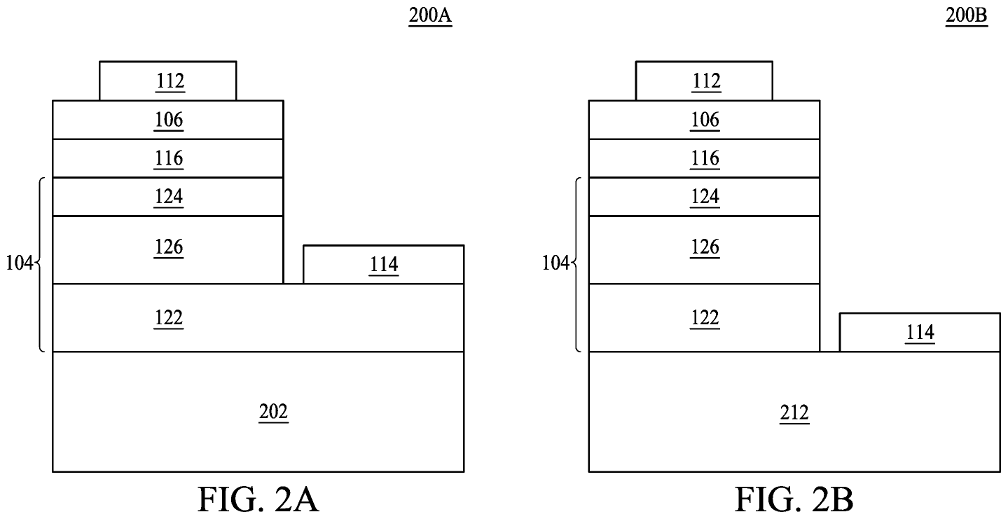

FIG. 2A and FIG. 2B illustrate a second embodiment 200A and a third embodiment 200B, respectively, of the LED structure, in accordance with some embodiments of the present invention. In some embodiments, the second embodiment 200A and the third embodiment 200B are planar type LED structures.

Referring to FIG. 2A, the second embodiment 200A includes a substrate 202, a light-generating structure 104 over the substrate 202, a first contact layer 116 (P-contact) over the light-generating structure 104, a spreading layer 106 over the first contact layer 116, and a first electrode 112 over the spreading layer 106. The spreading layer 106 is in contact with the P-type semiconductor layer (P-layer) 124 if the first contact layer 116 is absent. The substrate 202 has a lower side and an upper side opposite to the lower side, in which the upper side faces the light-generating structure 104. The first electrode 112, the spreading layer 106, the first contact layer 116 and the light-generating structure 104 are disposed over the upper side of the substrate 202.

A P-type semiconductor layer 124 (P-layer) and a light-emitting layer 126 of the light-generating structure 104 have widths (e.g., formed using a patterning operation) less than the width of an N-type semiconductor layer 122 (N-layer) of the light-generating structure 104. A portion of the N-type semiconductor layer 122 is therefore exposed through the light-emitting layer 126. A second electrode 114 is disposed over the exposed portion of the N-type semiconductor layer 122. In some embodiments, the second electrode 114 is disposed over the upper side of the substrate 202. In some embodiments, the second electrode 114 is adjacent to and isolated from the light-emitting layer 126.

In some embodiments, the substrate 202 is an electrically insulative or non-conductive substrate. In some embodiments, the substrate 202 is a conductive or semiconductive substrate. In some embodiments, the substrate 202 is transparent or opaque. In some embodiments, the substrate 202 is formed of Si, Ge, GaP, GaAs, InP, InAs, InSb, GaN, or the like.

In some embodiments, an intermediate member 118 (not shown in FIGS. 2A and 2B, but illustrated in FIG. 1) is disposed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent). In some embodiments, the intermediate member 118 includes indium tin oxide (ITO). In some embodiments, the intermediate member 118 includes Au, Ni, Cr, Al, Ti, Ag, Pt, a combination thereof, or any other suitable material.

Referring to FIG. 2B, the third embodiment 200B includes a substrate 212, a light-generating structure 104 over the substrate 212, a first contact layer 116 (P-contact) over the light-generating structure 104, a spreading layer 106 over the first contact layer 116, and a first electrode 112 over the spreading layer 106. The substrate 212 has a lower side and an upper side opposite to the lower side, in which the upper side faces the light-generating structure 104. In some embodiments, the first electrode 112, the spreading layer 106, the first contact layer 116 and the light-generating structure 104 are disposed over the upper side of the substrate 212.

The light-generating structure 104, which includes a P-type semiconductor layer 124 (P-layer), a light-emitting layer 126 and an N-type semiconductor layer 122 (N-layer), has a width less than the width of the substrate 212. A portion of the substrate 212 is therefore exposed through the light-generating structure 104. A second electrode 114 is disposed over the exposed portion of the substrate 212. In some embodiments, the second electrode 114 is adjacent to and isolated from the N-type semiconductor layer 122. In some embodiments, the second electrode 114 is disposed over the upper side of the substrate 212.

In some embodiments, the substrate 212 is a conductive or semiconductive substrate. In some embodiments, the substrate 212 is transparent or opaque. In some embodiments, the substrate 212 is formed of Si, Ge, GaP, GaAs, InP, InAs, InSb, GaN, or the like.

In some embodiments, an intermediate member 118 (not shown in FIG. 2B, but illustrated in FIG. 1) is disposed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent). In some embodiments, the intermediate member 118 includes indium tin oxide (ITO), Au, Ni, Cr, or any other suitable material.

In some embodiments, the first contact layer 116 in FIGS. 2A and 2B is doped with a dopant such as carbon, zinc, magnesium or other suitable acceptors for increasing electrical conductivity of the first contact layer 116. In some embodiments, the first contact layer 116 in FIGS. 2A and 2B is doped with a dopant concentration substantially equal to or greater than 1E18 atoms/cm³. In some embodiments, the first contact layer 116 is doped with a dopant concentration substantially equal to or greater than 2E18 atoms/cm³.

Referring to FIGS. 2A and 2B, the spreading layer 106 is disposed in an electrical conduction path between the first electrode 112 and the second electrode 114, wherein the electrical conduction path extends through the first contact layer 116 and the light-generating structure 104. The spreading layer 106 may have good transmittance at wavelengths of light both within and outside of the visible range, and may improve the current-spreading efficiency of the LED.

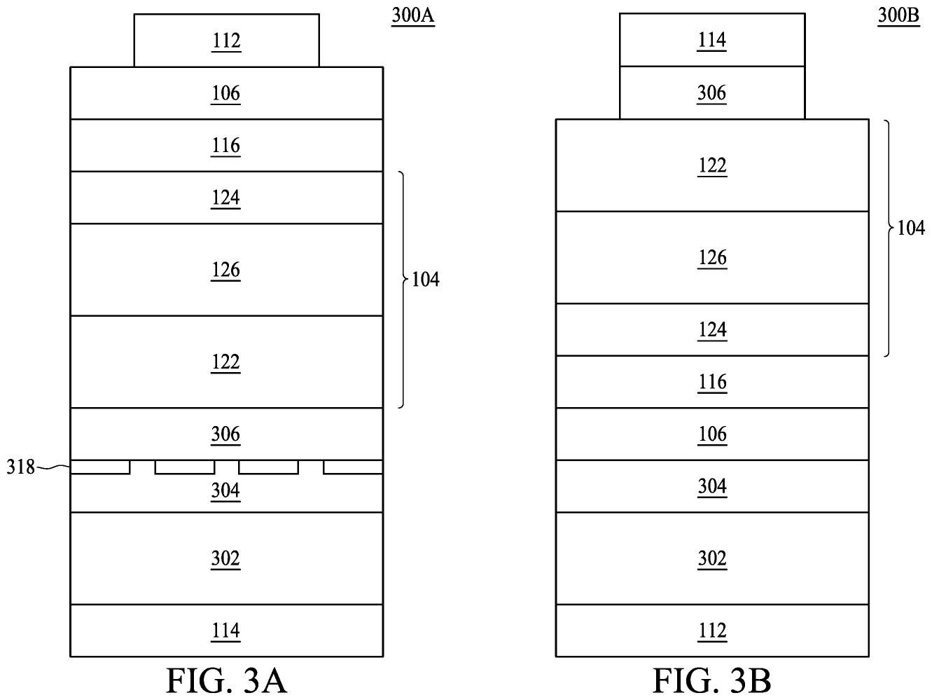

FIG. 3A and FIG. 3B illustrate a fourth embodiment 300A and a fifth embodiment 300B, respectively, of the LED structure, in accordance with some embodiments of the present invention. In some embodiments, the fourth embodiment 300A and the fifth embodiment 300B are vertical metal bonding LED structures. In some embodiments, the fourth embodiment 300A and the fifth embodiment 300B of the LED structure emit light at wavelengths of about 660 nm.

Referring to 3A, the fourth embodiment 300A includes a substrate 302, a conductive layer 304 over the substrate 302, a second contact layer 306 (which is also referred to as an N-side contact layer or an N-contact layer) over the conductive layer 304, a light-generating structure 104 over the second contact layer 306, a first contact layer 116 (P-contact) over the light-generating structure 104, and a spreading layer 106 over the first contact layer 116. A first electrode 112 is disposed over the spreading layer 106, and a second electrode 114 is disposed beneath the substrate 302. In some embodiments, the second contact layer 306 is disposed between the second electrode 114 and the light-generating structure 104.

The light-generating structure 104 may comprise an N-type semiconductor layer (N-layer) 122, a P-type semiconductor layer (P-layer) 124, and a light-emitting layer 126 between the N-type semiconductor layer 122 and the P-type semiconductor layer 124. In some embodiments, the spreading layer 106 is in contact with the P-type semiconductor layer (P-layer) 124 if the first contact layer 116 is absent. In some embodiments, the N-type semiconductor layer (N-layer) 122 is in contact with the conductive layer 304 if the second contact layer 306 is absent.

In some embodiments, the second contact layer 306 includes semiconductive material such as AlP, GaP, InP, AlGaP, AlInP, GaInP, AlGaInP, AlAs, GaAs, InAs, AlGaAs, AlinAs, GainAs, AlGaInAs, AlAsP, GaAsP, AlGaAsP, AlInAsP, GaInAsP, AlGaInAsP, or the like. In other embodiments, the second contact layer 306 includes semiconductive material such as AlSb, GaSb, InSb, AlGaSb, AlInSb, GaInSb, AlGaInSb, AlPSb, GaPSb, InPSb, AlGaPSb, AlInPSb, GaInPSb, AlGaInPSb, AlAsSb, GaAsSb, InAsSb, AlGaAsSb, AlInAsSb, GaInAsSb, AlGaInAsSb, AlPAsSb, GaPAsSb, InPAsSb, AlGaPAsSb, AlInPAsSb, GaInPAsSb, AlGaInPAsSb, or the like.

In some embodiments, an intermediate member 118 (not shown in FIG. 3A, but illustrated in FIG. 1) is disposed between the spreading layer 106 and the first contact layer 116, or between the spreading layer 106 and the P-type semiconductor layer 124 if the first contact layer 116 is absent. In some embodiments, the intermediate member 118 includes indium tin oxide (ITO). In some embodiments, the intermediate member 118 includes Au, Ni, Cr, Al, Ti, Ag, Pt, a combination thereof, or any other suitable material.

The substrate 302 has a lower side and an upper side opposite to the lower side, in which the upper side faces the light-generating structure 104. In some embodiments, the substrate 302 of the fourth embodiment 300A is a conductive substrate. In some embodiments, the substrate 302 is transparent or opaque. In some embodiments, the substrate 302 is formed of Si, Ge, GaP, GaAs, InP, InAs, InSb, GaN, or metal.

In some embodiments, the first electrode 112 includes metallic material such as Ti, Au, Pt or the like. In some embodiments, the second electrode 114 includes metallic material such as AuGe, AuSi, Au, Ni or the like.

In some embodiments, the conductive layer 304 serves as a reflective layer configured to reflect light generated by the light-emitting layer 126. As a result, the LED structure of the fourth embodiment 300A can provide improved light-emission efficiency. In some embodiments, the conductive layer 304 includes metallic material such as Au, Ag, Al, Cr, Ni or the like.

In some embodiments, a dielectric layer 318 is disposed between the conductive layer 304 and the second contact layer 306, as shown in FIG. 3A. In some embodiments, the dielectric layer 318 is disposed around an interface between the conductive layer 304 and the second contact layer 306. In some embodiments, the dielectric layer 318 comprises dielectric materials such as oxide, nitride or other suitable materials. The dielectric layer 318 is patterned to include vias such that portions of the conductive layer 304 extend through the vias and are electrically coupled to the second contact layer 306 for forming electrical connection. The dielectric layer 318 may aid in protecting the metallic color of the surface of the conductive layer 304 from being darkened during an annealing operation of the manufacturing process. As a result, portions of the conductive layer 304 that are separated from the second contact layer 306 by the dielectric layer can efficiently reflect the light generated by the light-emitting layer 126. In some embodiments, the conductive layer 304 includes electrically conductive contacts to electrically couple the conductive layer 304 to the second contact layer 306.

Referring to FIG. 3B, the fifth embodiment 300B includes a substrate 302, a conductive layer 304 over the substrate 302, a spreading layer 106 over the conductive layer 304, a first contact layer (P-contact) 116 over the spreading layer 106 (the spreading layer 106 is in contact with the P-type semiconductor layer (P-layer) 124 if the first contact layer 116 is absent), a light-generating structure 104 over the first contact layer 116, a second contact layer 306 (N-contact) over the light-generating structure 104, and a second electrode 114 over the second contact layer 306. A first electrode 112 is disposed below the substrate 302. In some embodiments, the first contact layer 116 couples the spreading layer 106 to a P-type semiconductor layer 124 (P-layer) of the light-generating structure 104. In some embodiments, the second contact layer 306 couples an N-type semiconductor layer (N-layer) 122 of the light-generating structure 104 to the second electrode 114. In some embodiments, an intermediate member 118 (not shown in FIG. 313, but illustrated in FIG. 1) is disposed between the spreading layer 106 and the first contact layer 116, or between the spreading layer 106 and the P-type semiconductor layer 124 if the first contact layer 116 is absent.

In some embodiments, the substrate 302 of the fifth embodiment 300B is a conductive substrate. In some embodiments, the substrate 302 is transparent or opaque. In some embodiments, the substrate 302 is formed of Si, Ge, GaP, GaAs, InP, InAs, InSb, GaN, or metal.

In some embodiments, the first contact layer 116 in FIGS. 3A and 3B is doped with a dopant, such as zinc, magnesium, carbon or other suitable acceptors, for increasing electrical conductivity of the first contact layer 116. In some embodiments, the first contact layer 116 in FIGS. 3A and 3B is doped with a dopant concentration substantially greater than or equal to 1E18 atoms/cm³. In some embodiments, the first contact layer 116 in FIGS. 3A and 3B is doped with a dopant concentration substantially greater than or equal to 1E19 atoms/cm³.

In some embodiments, the second contact layer 306 in FIGS. 3A and 3B is doped with a dopant, such as silicon or other suitable donors, for increasing electrical conductivity of the second contact layer 306. In some embodiments, the second contact layer 306 in FIGS. 3A and 3B is doped with a dopant concentration substantially greater than or equal to 1E18 atoms/cm'. In some embodiments, the second contact layer 306 in FIGS. 3A and 3B is doped with a dopant concentration substantially greater than or equal to 4E18 atoms/cm³.

In some embodiments, the spreading layer 106 of the fourth embodiment 300A and the fifth embodiment 300B is formed in an electrical conduction path between the first electrode 112 and the second electrode 114, wherein the electrical conduction path extends through the first contact layer 116, the light-generating structure 104, the second contact layer 306, the conductive layer 304 and the substrate 302. The spreading layer 106 may have good transmittance at wavelengths of light both within and outside of the visible range, and may improve the current-spreading efficiency of the LED.

The following description discusses a manufacturing process of the fifth embodiment 300B of the LED structure. In some embodiments, an epitaxial (EPI) structure is prepared or obtained. In some embodiments, the EPI structure is formed over a growth substrate (not shown). In some embodiments, the EPI structure includes the light-generating structure 104 disposed over the growth substrate. In some embodiments, the light-generating structure 104 includes the N-type semiconductor layer 122 (N-layer), the light-emitting layer 126 and the P-type semiconductor layer 124 (P-layer). In some embodiments, the growth substrate is formed of GaAs, InP or any other suitable material. In some embodiments, the first contact layer 116 is deposited on a side adjacent to the P-type semiconductor layer 124. In some embodiments, a second contact layer 306 is deposited on a side adjacent to the N-type semiconductor layer 122.

The spreading layer 106 is deposited over the first contact layer 116 by vacuum evaporation, vacuum coating or any other suitable operation. In some embodiments, the spreading layer 106 is disposed over the first contact layer 116 at a temperature of about 325° C. In some embodiments, the spreading layer 106 is coated over the first contact layer 116 at a pressure of about 3E-6 torr. In some embodiments, during the disposing of the spreading layer 106, an oxygen flow rate is about 4.6 sccm.

Next, a conductive layer 304 is formed over the spreading layer 106. The conductive layer 304 may be deposited over the spreading layer 106 using a vacuum deposition process with an electron beam gun (E-gun).

In some embodiments, an intermediate member 118 (not shown in FIG. 3B, but illustrated in FIG. 1) is formed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent).

With the above deposition parameters, the spreading layer 106 has a high transmittance (e.g., greater than about 90%) for an electromagnetic radiation at a wavelength of about 940 nm or above, and the spreading layer 106 has a sheet resistance of about 21.4 Ω/sq. Once disposing of the spreading layer 106 over the first contact layer 116, an electrical contact (e.g., ohmic contact) between the first contact layer 116 and the spreading layer 106 is formed.

Further, a substrate 302 is provided. The substrate 302 can be conductive or semiconductive. A surface of the substrate 302 is also coated with a bonding metal layer (comprising, e.g., adhesive metal) using a vacuum deposition process. In some embodiments, the bonding metal layer includes metallic material such as Au, Ag, Al, Ti, Pt or the like. Subsequently, a bonding process is performed for bonding the growth substrate and the EPI structure to the substrate 302. In some embodiments, the conductive layer 304 is bonded to the bonding metal layer.

After the bonding, the growth substrate is partially or completely removed by grinding, wet etching or any other suitable operation. In some embodiments, the growth substrate is thinned to a desired thickness. In some embodiments, the growth substrate is entirely removed, and as a result only the IPI structure, including the light-generating structure 104, the first contact layer 116, the spreading layer 106 and the conductive layer 304, is left over the substrate 302.

in addition, the material of the second electrode 114 is coated over the second contact layer 306 using the vacuum coating process. The materials of the second contact layer 306 and the second electrode 114 are then patterned into desired shapes of the second contact layer and the second electrode 114 by lithography, wet etching or any other suitable operation. Subsequently, an annealing process is performed at a temperature between 320° C. and 380° C. The annealing process facilitates formation of an ohmic contact between the second electrode 114 and the N-type semiconductor layer 122 or between the second electrode 114 and the second contact layer 306.

In some embodiments, the substrate 302 is thinned to a desired thickness by grinding, etching or any other suitable technique. In some embodiments, the first electrode 112 is formed by vacuum evaporation, vacuum coating or any other suitable operation. In some embodiments, a vacuum deposition process is performed for forming the first electrode 112. Subsequently, an annealing process is performed at a temperature between 250° C. and 350° C., such that an ohmic contact between the first electrode 112 and the substrate 302 is formed. Further, adhesion between the first electrode 112 and the substrate 302 is improved after the annealing process.

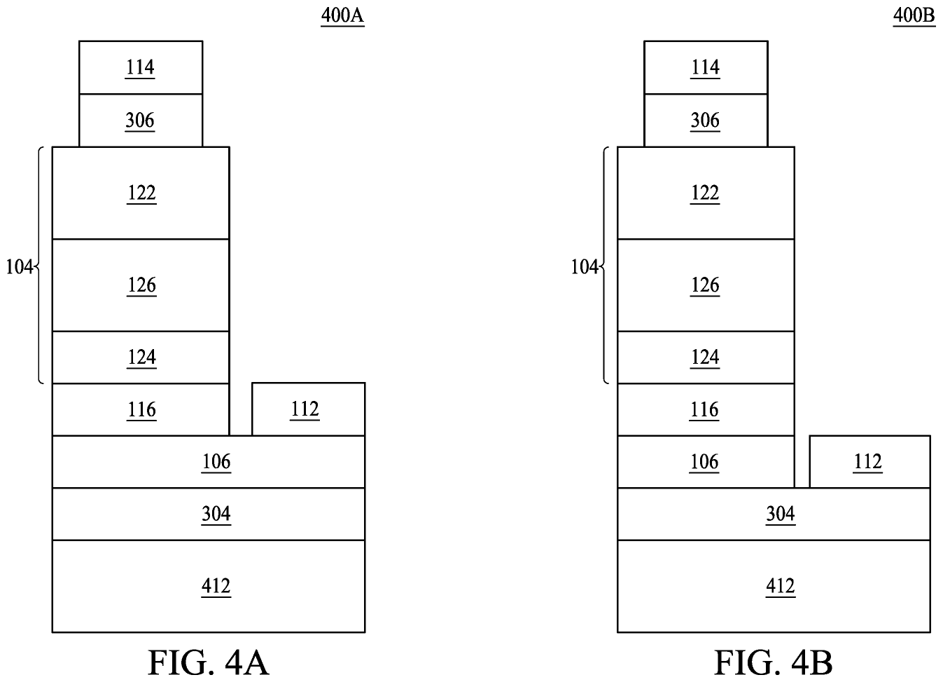

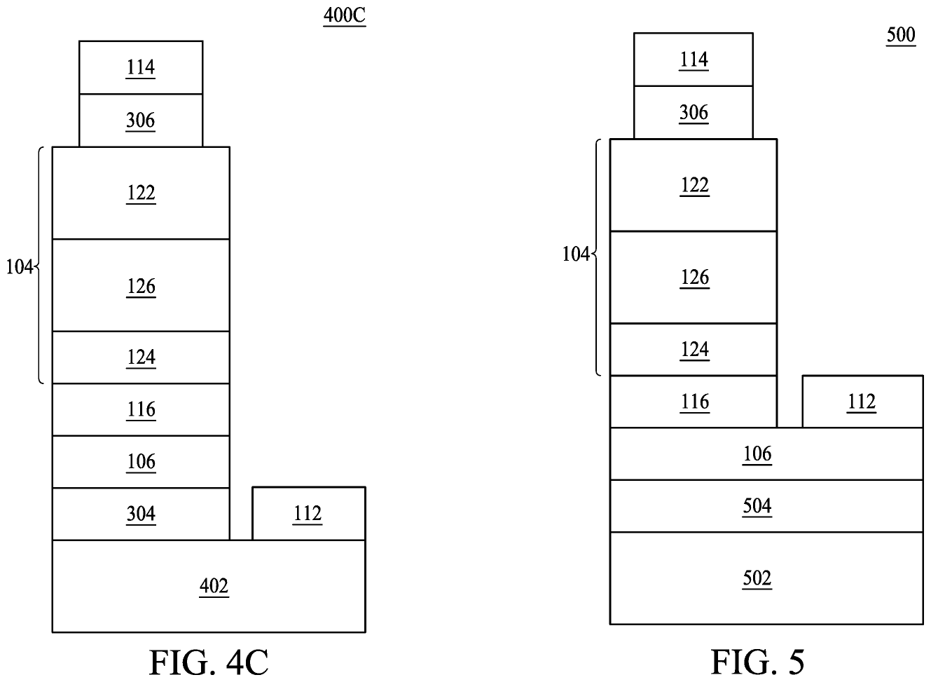

FIGS. 4A to 4C illustrate a sixth embodiment 400A, a seventh embodiment 400B, and an eighth embodiment 400C, respectively, of the LED structure, in accordance with some embodiments of the present invention. In some embodiments, the sixth embodiment 400A, the seventh embodiment 400B and the eighth embodiment 400C are planar metal bonding LED structures.

Referring to FIG. 4A, the sixth embodiment 400A includes a substrate 412, a. conductive layer 304 over the substrate 412, a spreading layer 106 over the conductive layer 304, a first contact layer 116 (P-contact layer) over the spreading layer 106, and a light-generating structure 104 over the first contact layer 116. The spreading layer 106 is in contact with the P-type semiconductor layer (P-layer) 124 if the first contact layer 116 is absent. A second contact layer 306 (N-contact) is disposed over an N-type semiconductor layer 122 (N-layer) of the light-generating structure 104, and a second electrode 114 is disposed over the second contact layer 306. The substrate 412 a lower side and an upper side opposite to the lower side, in which the upper side faces the light-generating structure 104.

In some embodiments, the light-generating structure 104 and the first contact layer 116 have widths (e.g., formed using a patterning operation) less than the width of the spreading layer 106. A portion of the spreading layer 106 is therefore exposed through the first contact layer 116. A first electrode 112 is disposed over the exposed portion of the spreading layer 106. In some embodiments, the first electrode 112 and the second electrode 114 are disposed over the upper side of the substrate 412. In some embodiments, the first electrode 112 is adjacent to and spaced apart from the first contact layer 116.

In some embodiments, the substrate 412 is an electrically insulative or non-conductive substrate. In some embodiments, the substrate 412 is a conductive or semiconductive substrate. In some embodiments, the substrate 412 is transparent or opaque. In some embodiments, the substrate 412 is formed of Si, Ge, GaP, GaAs, InP, InAs, InSb, GaN, metal, ceramic, sapphire, or SiO₂.

In some embodiments, an intermediate member 118 (not shown in FIG. 4A, but illustrated in FIG. 1) is disposed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent). In sonic embodiments, the intermediate member 118 includes indium tin oxide (ITO). In some embodiments, the intermediate member 118 includes Au, Ni, Cr, Al, Ti, Ag, Pt, a combination thereof, or any other suitable material.

In some embodiments, the spreading layer 106 is formed in an electrical conduction path between the second electrode 114 and the first electrode 112, wherein the electrical conduction path extends through the second contact layer 306, the light-generating structure 104 and the first contact layer 116 (and, in some embodiments, through and the substrate 412). The spreading layer 106 may have good transmittance at wavelengths of light both within and outside of the visible range, and may improve the current-spreading efficiency of the LED.

Referring to FIG. 4B, the seventh embodiment 400B is similar to the sixth embodiment 400A, except that the spreading layer 106 is further patterned to expose a portion of the conductive layer 304. The first electrode 112 is disposed on the exposed portion of the conductive layer 304 and is spaced apart from the spreading layer 106 and the first contact layer 116. The first electrode 112 is disposed adjacent to the spreading layer 106.

In some embodiments, the spreading layer 106 is formed in an electrical conduction path between the second electrode 114 and the first electrode 112, wherein the electrical conduction path extends through the second contact layer 306, the light-generating structure 104, the first contact layer 116 and the conductive layer 304 (and, in some embodiments, through the substrate 412). The spreading layer 106 may have good transmittance at wavelengths of light both within and outside of the visible range, and may improve the current-spreading efficiency of the LED.

Referring to FIG. 4C, the eighth embodiment 400C is similar to the seventh embodiment 400B, except that the substrate 412 is replaced with a substrate 402 and the conductive layer 304 is further patterned to expose a portion of the substrate 402. The substrate 402 has a lower side and an upper side opposite to the lower side, in which the upper side faces the light-generating structure 104. In some embodiments, a first electrode 112 is disposed over the upper side of the substrate 402. The first electrode 112 may be disposed over the exposed portion of the substrate 402. In some embodiments, the first electrode 112 is adjacent to and spaced apart from the conductive layer 304.

In some embodiments, the substrate 402 is a conductive or semiconductive substrate. In some embodiments, the substrate 402 is transparent or opaque. In some embodiments, the substrate 402 is formed of Si, Ge, GaP, GaAs, InP, InAs, InSb, GaN or metal.

In some embodiments, an intermediate member 118 (not shown in FIG. 4C, but illustrated in FIG. 1) is disposed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent). In some embodiments, the intermediate member 118 includes indium tin oxide (ITO), Au, Ni, Cr, or any other suitable material.

In some embodiments, the spreading layer 106 is formed in an electrical conduction path between the second electrode 114 and the first electrode 112, wherein the electrical conduction path passes through the second contact layer 306, the light-generating structure 104, the first contact layer 116, the conductive layer 304 and the substrate 402. The spreading layer 106 may have good transmittance at wavelengths of light both within and outside of the visible range, and may improve the current-spreading efficiency of the LED.

In some embodiments, the first contact layer 116 in FIGS. 4A to 4C is doped with a dopant, such as zinc, magnesium, carbon or other suitable acceptors, for increasing electrical conductivity of the first contact layer 116. In some embodiments, the first contact layer 116 in FIGS. 4A to 4C is doped with a dopant concentration substantially greater than or equal to 1E18 atoms/cm³. In some embodiments, the first contact layer 116 in FIGS. 4A to 4C is doped with a dopant concentration substantially greater than or equal to 1E19 atoms/cm³.

In some embodiments, the second contact layer 306 in FIGS. 4A to 4C is doped with a dopant, such as silicon or other suitable donors, for increasing electrical conductivity of the second contact layer 306. In some embodiments, the second contact layer 306 in FIGS. 4A to 4C is doped with a dopant concentration substantially greater than or equal to 1E18 atoms/cm³. In some embodiments, the second contact layer 306 in FIGS. 4A to 4C is doped with a dopant concentration substantially greater than or equal to 4E18 atoms/cm³.

FIG. 5 illustrates a ninth embodiment 500 of the LED structure in accordance with some embodiments of the present invention. In some embodiments, the ninth embodiment 500 is a planar transparent bonding LED structure. In some embodiments, the ninth embodiment 500 of the LED structure emits light at a wavelength of about 940 nm.

Referring to 5, the ninth embodiment 500 includes a substrate 502, a bonding layer 504 over the substrate 502, a spreading layer 106 over the bonding layer 504, a first contact layer 116 (P-contact layer) over the spreading layer 106, and a light-generating structure 104 over the first contact layer 116. In some embodiments, the first contact layer 116 is absent, and thus the spreading layer 106 is in contact with the P-type semiconductor layer 124 of the light-generating structure 104. The substrate 502 has a lower side and an upper side opposite to the lower side, in which the upper side faces the light-generating structure 104.

A second contact layer (N-contact layer) 306 is disposed over an N-type semiconductor layer 122 (N-layer) of the light-generating structure 104, and a second electrode 114 is disposed over the second contact layer 306.

The light-generating structure 104 and the first contact layer 116 are patterned to expose a portion of the spreading layer 106. A first electrode 112 is disposed over the exposed portion of the spreading layer 106 and is spaced apart from the first contact layer 116. The first electrode 112 is disposed adjacent to the first contact layer 116. In some embodiments, the first electrode 112 and the second electrode 114 are disposed over the upper side of the substrate 502. In some embodiments, the first electrode 112 is in physical contact with the spreading layer 106. In some embodiments, the first contact layer 116 is absent, and thus the P-type semiconductor layer 124 is in physical contact with the spreading layer 106.

The spreading layer 106 has a lower side and an upper side opposite to the lower side, in which the upper side faces the light-generating structure 104. In some embodiments, the first electrode 112 and the second electrode 114 are disposed over the upper side of the spreading layer 106.

In some embodiments, the substrate 502 is a transparent or opaque substrate. In some embodiments, the substrate 502 is a conductive, semiconductive, non-conductive or electrically insulative substrate. In some embodiments, the substrate 502 includes Si, Ge, GaP, GaAs, InP, InAs, InSb, GaN, Al₂O₃, SiO₂, SiN, sapphire, metal, or the like.

In some embodiments, the bonding layer 504 used in the transparent bonding type LED structure may be formed of a transparent material, such as polyimide benzocyclobutene (BCB) or perfluorocyclobutane (PFOB). In some embodiments, the bonding layer 504 of the transparent bonding type LED structure forms an oxide-to-oxide bonding, such as SiO₂-SiO₂ bonding. In some embodiments, the transparent bonding layer is bonded using atomic diffusion bonding.

in some embodiments, the first contact layer 116 has a rough surface (not shown) facing the spreading layer 106. In some embodiments, the rough surface is formed of peaks or teeth-shape protrusions. In some embodiments, the spreading layer 106 has a rough surface facing the first contact layer 116.

In some embodiments, the second electrode 114 includes metallic material such as AuGe, Au, Al, Ti or the like. In some embodiments, the first electrode 112 includes metallic material such as Ti, Pt, Au or the like.

In some embodiments, an intermediate member 118 (not shown in FIG 5, but illustrated in FIG. 1) is disposed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116, or the electrical contact (e.g., ohmic contact) between the spreading layer 106 and the P-type semiconductor layer 124 if the first contact layer 116 is absent. In some embodiments, the intermediate member 118 includes indium tin oxide (ITO). In sonic embodiments, the intermediate member 118 includes Au, Ni, Cr, Al, Ti, Ag, Pt, a combination thereof, or any other suitable material.

In some embodiments, the first contact layer 116 in FIG. 5 is doped with a dopant, such as zinc, magnesium, carbon or other suitable acceptors, for increasing electrical conductivity of the first contact layer 116. In some embodiments, the first contact layer 116 in FIG. 5 is doped with a dopant concentration substantially greater than or equal to 1E18 atoms/cm³. In some embodiments, the first contact layer 116 in FIG. 5 is doped with a dopant concentration substantially greater than or equal to 1E19atoms/cm³.

In some embodiments, the second contact layer 306 in FIG. 5 is doped with a dopant, such as silicon or other suitable donors, for increasing electrical conductivity of the second contact layer 306. In some embodiments, the second contact layer 306 in FIG. 5 is doped with a dopant concentration substantially greater than or equal to 1E18 atoms/cm³ in some embodiments, the second contact layer 306 in FIG. 5 is doped with a dopant concentration substantially greater than or equal to 4E18 atoms/cm³.

Referring to FIG. 5, the spreading layer 106 is formed in an electrical conduction path between the second electrode 114 and the first electrode 112, wherein the electrical conduction path extends through the second contact layer 306, the light-generating structure 104 and the first contact layer 116. The spreading layer 106 may have good transmittance at wavelengths of light both within and outside of the visible range, and may improve the current-spreading efficiency of the LED.

The following description discusses a manufacturing process of the ninth embodiment 500 of the LED structure. In some embodiments, an epitaxial (EPI) structure is prepared or obtained. In some embodiments, the EPI structure is formed over a growth substrate. In some embodiments, the EPI structure includes the light-generating structure 104 disposed over the growth substrate. In some embodiments, the light-generating structure 104 comprises the P-type semiconductor layer 124 (P-layer), the light-emitting layer 126 and the N-type semiconductor layer (N-layer) 122.

In some embodiments, the first contact layer 116 (P-contact) is formed over the light-generating structure 104. A surface of the first contact layer 116 is roughened by lithography, thin film techniques, etching or any other suitable operation. The roughened surface is configured to increase surface area for light emission as well as increase an adhesiveness of the surface of the first contact layer 116.

Subsequently, the spreading layer 106 is formed on the first contact layer 116 by vacuum evaporation, vacuum coating or any other suitable operation. Once the formation of the spreading layer 106 on the first contact layer 116, an electrical contact (e.g., ohmic contact) between the spreading layer 106 and the first contact layer 116 is formed.

In some embodiments, the intermediate member 118 is formed between the spreading layer 106 and the first contact layer 116 (or between the spreading layer 106 and the P-type semiconductor layer 124 if the first contact layer 116 is absent) for forming or improving the electrical contact (e.g., ohmic contact) between the spreading layer 106 and the first contact layer 116 (or between the spreading layer 106 and the P-type semiconductor layer 124 if the first contact layer 116 is absent).

Next, a substrate 502 is provided, and a transparent adhesive layer is uniformly disposed over the surfaces of the spreading layer 106 and the substrate 502 by coating processes. In some embodiments, the transparent adhesive layer can be made of BCB, PT, silicone or other transparent material. Subsequently, the growth substrate and the EPI structure are bonded over the substrate 502 by compression or other suitable operation. In some embodiments, a bonding operation is conducted at high temperature and high pressure. In some embodiments, the transparent adhesive layer is adhered to a bonding layer 504.

After the bonding operation, the growth substrate is partially or completely removed by grinding, wet etching or other suitable operation. In some embodiments, the growth substrate is thinned to a desired thickness. In some embodiments, the growth substrate is entirely removed, and as a result, only the EPI structure that includes the light-generating structure 104, the first contact layer 116 and the spreading layer 106 is left over the substrate 502.

In addition, a vacuum deposition process is performed for disposing the second electrode 114. After the disposing of the second electrode 114, the second electrode 114 is patterned as desired by lithography, wet etching or other suitable operation. Further, the vacuum deposition process is performed for forming the first electrode 112 Subsequently, an annealing process is performed at a temperature between 320° C. and 350° C. for increasing an adhesion between the first electrode 112 and the spreading layer 106.

The following Tables 1-3 list parameters of the epitaxial structures according to some embodiments of the present invention.

TABLE 1
Epitaxial structure of Vertical type LED (for example, the first embodiment 100)

| | | | | | | Wavelength |
|---|---|---|---|---|---|---|
| Layer | Material | X (%) | Y (%) | Dopant | Thickness | (λ) |
| P-contact layer | InGaAs | — | — | Zn | 0.05-0.1 μm | — |
| P-layer | InP | — | — | Zn | 3.0-8.0 μm | — |
| Light-emitting | (AlₓGa₁₋ₓ)_{y}In_{1-y}As | 0-100 | 0-100 | — | 1.0-2.0 μm | 1300 nm |
| layer | | | | | | |
| N-layer | InP | — | — | Si | 0.5-1.5 μm | — |
| Substrate | InP | — | — | — | — | — |

TABLE 2
Epitaxial structure of Vertical Metal Bonding type LED (for example,
the fourth embodiment 300A or the fifth embodiment 300B)

| | | | | | | Wavelength |
|---|---|---|---|---|---|---|
| Layer | Material | X (%) | Y (%) | Dopant | Thickness | (λ) |
| P-contact layer | GaAsₓP₁₋ₓ | 0-100 | — | C | 0.05-0.1 μm | — |
| P-layer | (AlₓGa₁₋ₓ)_{y}In_{1-y}p | 0-100 | 40-60 | Mg | 1.0-3.0 μm | — |
| Light-emitting | (AlₓGa₁₋ₓ)_{y}In_{1-y}P | 0-100 | 40-60 | — | 0.4-2.0 μm | 660 nm |
| layer | | | | | | |
| N-layer | (AlₓGa₁₋ₓ)_{y}In_{1-y}P | 0-100 | 40-60 | Si | 3.0-5.0 μm | — |
| N-contact layer | GaAs | — | — | Si | 0.1~0.5 μm | — |
| Substrate | GaAs | — | — | — | — | — |

TABLE 3
Epitaxial structure of Planar Transparent Bonding
type LED (for example, the ninth embodiment 500)

| | | | | | | Wavelength |
|---|---|---|---|---|---|---|
| Layer | Material | X (%) | Y (%) | Dopant | Thickness | (λ) |
| P-contact layer | GaAsₓP₁₋ₓ | 0-100 | — | C | 0.05-0.1 μm | — |
| P-layer | AlₓGa₁₋ₓAs | 0-100 | — | Mg | 1.0-3.0 μm | — |
| Light-emitting | InₓGa₁₋ₓAs | 0-100 | — | — | 0.4-2.0 μm | 940 nm |
| layer | | | | | | |
| N-layer | AlₓGa₁₋ₓAs | 0-100 | — | Si | 3.0-8.0 μm | — |
| N-contact layer | GaAs | — | — | Si | 0.1~0.5 μm | — |
| Substrate | GaAs | — | — | — | — | — |

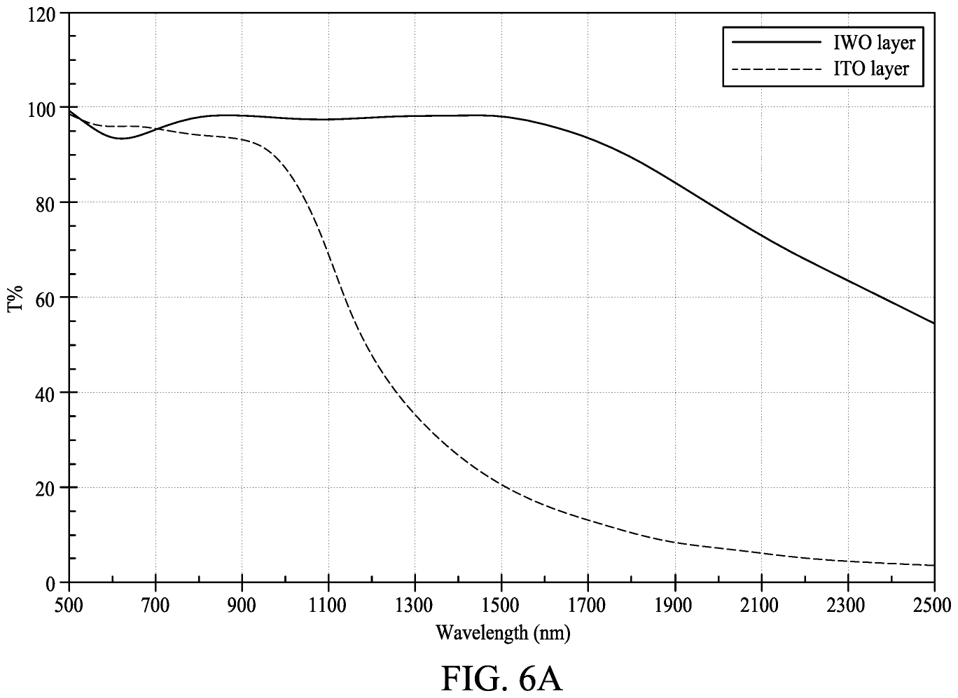

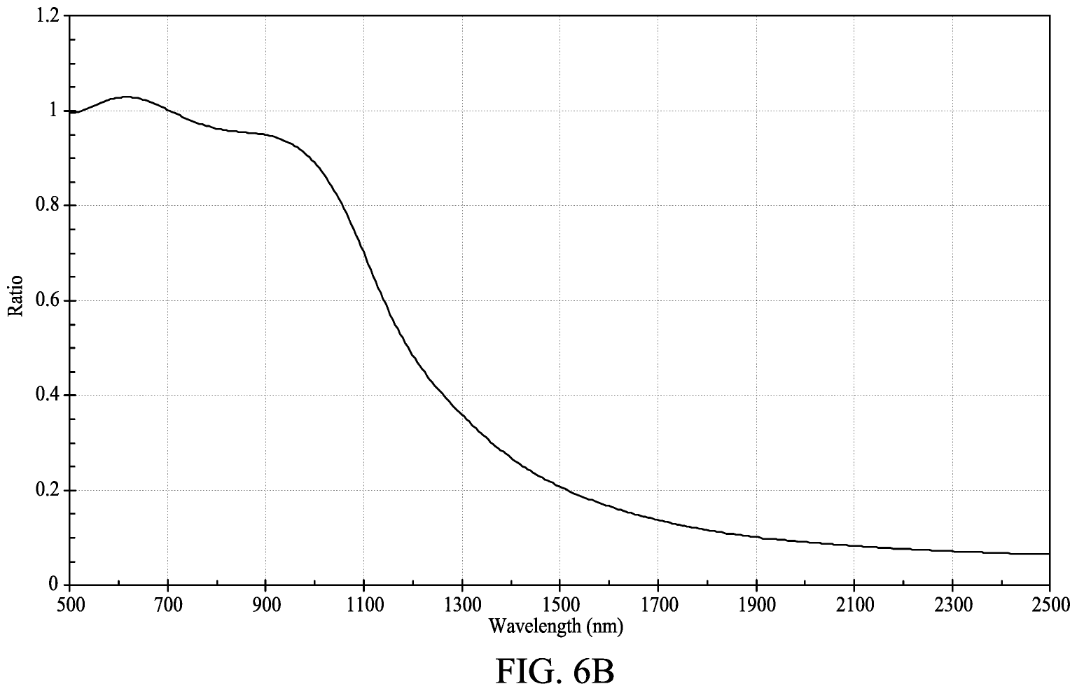

FIGS. 6A and 6B show comparative transmittances of IWO and ITO materials, in accordance with some embodiments of the present invention. A layer of the proposed spreading layer 106 formed of an IWO material and a layer formed of ITO material evaporated over a substrate (e.g., sapphire), and measurements of their transmittance values are taken using a measurement tool. In FIG. 6A, the transmittance of the spreading layer 106 using an IWO material is indicated as a solid line, while the transmittance of the layer formed of an ITO material is indicated as a dashed line. In FIGS. 6A and 6B, the X-axis represents the wavelength, in nanometers, of electromagnetic radiation. In FIG. 6A, the Y-axis represents the transmittance in terms of percentage (T %); in FIG. 6B, the Y-axis represents the transmittance ratio of the transmittance of the ITO layer to the transmittance of the IWO layer.

FIG. 6A shows that the spreading layer 106 formed of an MO material (solid line) provides a greater transmittance of the received radiation than the layer formed of ITO material (dashed line) across a wide spectrum from about 500 nm to about 2500 rim. For example, the spreading layer 106 using IWO material provides a transmittance greater than or equal to about 50% at wavelengths between about 500 nm and about 2500 nm. In some embodiments, a ratio of the transmittance at a first wavelength of about 2500 rim to the transmittance at a second wavelength of about 500 nm is substantially greater than or equal to 50% for the spreading layer 106 using the IWO material. In contrast, the layer formed of ITO material provides a transmittance similar to that of the spreading layer 106 using MO material at wavelengths less than about 700 nm, but the transmittance of the layer using ITO material drops rapidly at wavelengths increasing above 700 nm to less than 10% at the wavelength of about 2500 nm.

FIG. 6B shows a curve of the transmittance ratio between the layer formed of the ITO material and the spreading layer 106 formed of the IWO material, The curve reveals that although the layer formed of the ITO material has a comparable performance to the spreading layer 106 formed of the IWO material at wavelengths less than about 700 nm, the ratio drops rapidly at wavelengths above 700 nm, The ratio is reduced to less than 10% at the wavelength of about 2500 nm. The performance advantage of the spreading layer 106 formed of IWO material in the wavelengths above 700 nm is thus clear.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting diode structure, comprising:
a substrate;
a light-generating structure disposed over the substrate;
a first electrode adjacent to a first side of the light-generating structure;
a second electrode adjacent to a second side of the light-generating structure opposite to the first side; and
a tungsten-doped oxide layer disposed in an electrical conduction path between the light-generating structure and one of the first electrode and the second electrode.

2. The light-emitting diode structure of claim 1, wherein the tungsten-doped oxide layer includes at least one of indium tungsten oxide (IWO), zinc tungsten oxide (ZnWO), and copper tungsten oxide (CuWO).

3. The light-emitting diode structure of claim 1, wherein the light-generating structure comprises an N-type semiconductor layer, a P-type semiconductor layer and a light-emitting layer between the N-type and P-type semiconductor layers, wherein the tungsten-doped oxide layer is proximal to the P-type semiconductor layer and distal to the N-type semiconductor layer.

4. The light-emitting diode structure of claim 3, further comprising a first contact layer between the P-type semiconductor layer and the tungsten-doped oxide layer, wherein the first contact layer couples the P-type semiconductor layer to the tungsten-doped oxide layer.

5. The light-emitting diode structure of claim 4, wherein the first contact layer comprises a dopant formed of carbon, zinc or magnesium.

6. The light-emitting diode structure of claim 5, wherein the first contact layer comprises a dopant concentration substantially greater than or equal to 1E18 atoms/cm³.

7. The light-emitting diode structure of claim 3, further comprising an intermediate member between the tungsten-doped oxide layer and the light-generating structure, wherein an electrical contact is formed between the tungsten-doped oxide layer and the P-type semiconductor layer.

8. The light-emitting diode structure of claim 7, wherein a portion of the light-generating structure is exposed from the intermediate member.

9. The light-emitting diode structure of claim 7, wherein the intermediate member comprises at least one of indium tin oxide (ITO), Au, Ni or Cr, Al, Ti, Ag and Pt.

10. The light-emitting diode structure of claim 1, further comprising a conductive layer disposed between the substrate and the tungsten-doped oxide layer and configured to reflect light generated by the light-generating structure.

11. The light-emitting diode structure of claim 1, wherein a ratio of a transmittance of the tungsten-doped oxide layer of electromagnetic radiation at a first wavelength of about 2500 nm to a transmittance of the tungsten-doped oxide layer of electromagnetic radiation at a second wavelength of about 500 nm is substantially greater than or equal to 50%.

12. The light-emitting diode structure of claim 1, wherein a transmittance of the tungsten-doped oxide layer of electromagnetic radiation at wavelengths between about 500 nm and about 2500 nm is substantially greater than or equal to 50%.

13. A light-emitting diode structure, comprising:
a substrate having a first side;
a light-generating structure disposed over the first side of the substrate;
a first electrode disposed over the light-generating structure and the first side of the substrate;
a second electrode disposed over the first side of the substrate; and
a tungsten-doped oxide layer disposed in an electrical conduction path between the light-generating structure and one of the first electrode and the second electrode.

14. The light-emitting diode structure of claim 13, further comprising a first contact layer coupling the tungsten-doped oxide layer to a P-type semiconductor layer of the light-generating structure, wherein the first contact layer comprises a dopant concentration substantially greater than or equal to 1E18 atoms/cm³.

15. The light-emitting diode structure of claim 13, wherein a ratio of a transmittance of the tungsten-doped oxide layer of electromagnetic radiation at a first wavelength of about 2500 nm to a transmittance of the tungsten-doped oxide layer of electromagnetic radiation at a second wavelength of about 900 nm is substantially greater than or equal to 50%.

16. The light-emitting diode structure of claim 13, wherein a transmittance of the tungsten-doped oxide layer of electromagnetic radiation at wavelengths between about 900 nm and about 2500 nm is substantially greater than or equal to 50%.

17. A light-emitting diode structure, comprising:
a substrate;
a bonding layer over the substrate;
a tungsten-doped oxide layer having a first side and disposed over the bonding layer;
a light-generating structure disposed over the first side of the tungsten-doped oxide layer;
a first electrode disposed over the light-generating structure; and
a second electrode disposed adjacent to the light-generating structure and over the first side of the tungsten-doped oxide layer.

18. The light-emitting diode structure of claim 17, wherein the second electrode is in physical contact with the tungsten-doped oxide layer.

19. The light-emitting diode structure of claim 17, wherein the substrate includes a transparent non-conductive material.

20. The light-emitting diode structure of claim 17, wherein the bonding layer includes polyimide (PI), benzocyclobutene (BCB) or pertluorocyclobutane (PFCB).
